(19) United States
(12) Patent Application Publication
(10) Pub. No.: US 2026/0047136 A1
(43) Pub. Date: Feb. 12, 2026

(54) SEMICONDUCTOR DEVICE AND METHOD OF FORMING THEREOF

(71) Applicant: TAIWAN SEMICONDUCTOR MANUFACTURING COMPANY, LTD., Hsinchu (TW)

(72) Inventors: Cheng-I LIN, Hsinchu (TW); Cheng-Yu WEI, Taoyuan City (TW); Shu-Han CHEN, Hsinchu City (TW); Chi On CHUI, Hsinchu City (TW)

(73) Assignee: TAIWAN SEMICONDUCTOR MANUFACTURING COMPANY, LTD., Hsinchu (TW)

(21) Appl. No.: 18/796,098

(22) Filed: Aug. 6, 2024

(51) Int. Cl. H01L 29/423; H01L 21/28; H01L 21/306; H01L 21/8234; H01L 27/088; H01L 29/06; H01L 29/08; H01L 29/66; H01L 29/775; H01L 29/786

(52) U.S. Cl. CPC H10D 30/6735; H01L 21/28202; H01L 21/30608; H10D 30/014; H10D 30/43; H10D 30/6757; H10D 62/115; H10D 62/121; H10D 62/151; H10D 64/017; H10D 64/021; H10D 84/0151; H10D 84/038; H10D 84/83

(57) ABSTRACT

A method of forming a semiconductor device includes a number of operations. A dielectric layer is formed over a plurality of nanostructures arranged in a vertical manner and an isolation structure adjacent the nanostructures. The dielectric layer is nitridated. A vertical portion of the nitridated dielectric layer over a sidewall of the nanostructure is removed, wherein a first horizontal portion of the nitridated dielectric layer remains over the isolation structure, and a second horizontal portion of the nitridated dielectric layer remains over a topmost one of the nanostructures. A source/drain region is formed through the second horizontal portion of the nitridated dielectric layer and the nanostructures. A gate structure is formed and wraps around the nanostructures.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 10 illustrate cross-section views of forming a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The present disclosure is generally related to integrated circuit (IC) structures and methods of forming the same, and more particularly to fabricating gate-all-around (GAA) transistors. It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Various embodiments of the present disclosure relate to a nanosheet semiconductor device structure having protection hard masks over isolation oxide. In the gate replacement (RPG) process, etching step(s) may potentially damage the oxide material in the shallow trench isolation (STI) regions. Such damage can lead to dishing or voids in the oxide material in the STI regions, which may degrade device performance or increase the risk of leakage current between metal gates. To mitigate this issue, the present disclosure in various embodiments provides additional protection hard masks over the oxide material in the STI regions. The protection hard masks serve to shield the STI regions from damage during etching step(s) in the RPG process. In some embodiments, the protection hard masks are formed by nitridating a dielectric layer formed over the STI regions before the RPG process begins. In some embodiments, the nitridation process for forming the protection hard masks may include a directional plasma nitridation process and/or a thermal nitridation process.

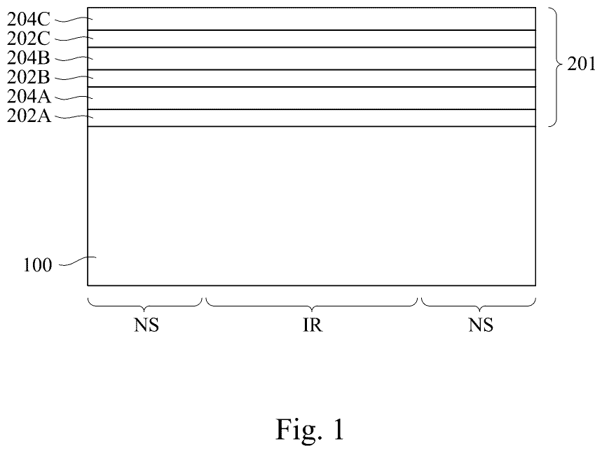

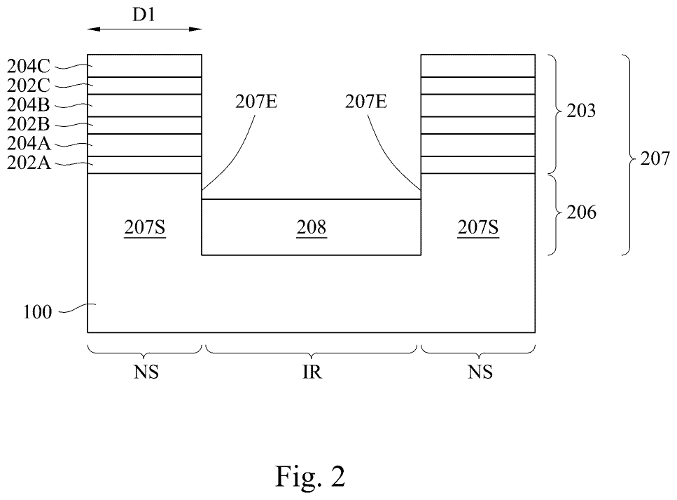

Reference is made to FIGS. 1 through 10. FIGS. 1 through 10 illustrate cross-sectional views of forming a semiconductor device, in accordance with some embodiments. FIGS. 1 through 10 illustrate the cross-sectional views along a longitudinal axis of the nanostructures 203 as described in FIG. 2, in accordance with some embodiments.

FIG. 1 illustrates a cross-sectional view of forming a multi-layer stack 201 over a substrate 100, in accordance with some embodiments.

In FIG. 1, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Further in FIG. 1, a multi-layer stack 201 is formed over the substrate 100. The multi-layer stack 201 includes alternating layers of first semiconductor layers 202A-C (collectively referred to as first semiconductor layers 202) and second semiconductor layers 204A-C (collectively referred to as second semiconductor layers 204). For purposes of illustration and as discussed in greater detail below, the first semiconductor layers 202 will be removed and the second semiconductor layers 204 will be patterned to form channel regions of GAA-FETs.

The multi-layer stack 201 is illustrated as including three layers of each of the first semiconductor layers 202 and the second semiconductor layers 204 for illustrative purposes. In some embodiments, the multi-layer stack 201 may include any number of the first semiconductor layers 202 and the second semiconductor layers 204. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of GAA-FETs.

Reference is made to FIG. 2 to illustrate a cross-sectional view of forming a fin structure 206 in the substrate 100 and forming nanostructures over the fin structure 206, in accordance with some embodiments. FIG. 2 further illustrates forming an isolation region 208 over the substrate 100.

As illustrated in FIG. 2, fin structures 206 are formed in the substrate 100 and nanostructures 203 are formed in the multi-layer stack 201, in accordance with some embodiments. Each fin structure 206 and its overlying nanostructures 203 can be collectively referred to as a semiconductor fin 207 each having longest sides 207S extending along a longitudinal or lengthwise direction D1, and longitudinal ends 207E spaced apart along the longitudinal direction D1. In some embodiments, the nanostructures 203 and the fin structures 206 may be formed in the multi-layer stack 201 and the substrate 100, respectively, by etching trenches in the multi-layer stack 201 and the substrate 100. Each fin structure 206 and overlying nanostructures 203 can be collectively referred to as a semiconductor fin extending from the substrate 100. The etching may be any acceptable etch process, such as a reactive ion etch (RIE), neutral beam etch (NBE), the like, or a combination thereof. The etching may be anisotropic. Forming the nanostructures 203 by etching the multi-layer stack 201 may further define first nanostructures 202A-C (collectively referred to as the first nanostructures 202) from the first semiconductor layers 202 and define second nanostructures 204A-C (collectively referred to as the second nanostructures 204) from the second semiconductor layers 204. The first nanostructures 202 and the second nanostructures 204 may further be collectively referred to as nanostructures 203.

The fin structures 206 and the nanostructures 203 may be patterned by any suitable method. For example, the fin structures 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 206. While each of the fin structures 206 and the nanostructures 203 are illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

As illustrated in FIG. 2, a shallow trench isolation (STI) region 208 is formed between longitudinal ends 207E of adjacent the fin structures 206. The STI region 208 may be an isolation structure formed between the fin structures 206. The STI regions 208 may be formed by depositing an insulation material over the substrate 100, the fin structures 206, and nanostructures 203, and between adjacent fin structures 206. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100, the fin structures 206, and the nanostructures 203. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI region 208. The insulation material is recessed such that upper portions of fin structures 206 protrude from between neighboring STI regions 208. Further, the top surfaces of the STI regions 208 may have a flat surface as illustrated, a convex surface, a concave surface (such as dishing), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etches the material of the insulation material at a faster rate than the material of the fin structures 206 and the nanostructures 203). For example, an oxide removal using, for example, dilute hydrofluoric (dHF) acid may be used.

The process described above with respect to FIGS. 1 and 2 is just one example of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Further in FIG. 2, appropriate wells (not separately illustrated) may be formed in the fin structures 206 and/or the nanostructures 203. In some embodiments with different well types in different device regions (e.g., NFET region and PFET region), different implant steps may be achieved using a photoresist or other masks (not separately illustrated). For example, a photoresist may be formed over the fin structures 206 and the STI regions 208 in the NFET region and the PFET region. The photoresist is patterned to expose the PFET region. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the PFET region, and the photoresist may act as a mask to substantially prevent the first impurities from being implanted into the NFET region. After the implant, the photoresist is removed, such as by an acceptable ashing process.

Following or prior to the implanting of the PFET region, a photoresist or other masks (not separately illustrated) is formed over the fin structures 206, the nanostructures 203, and the STI regions 208 in the NFET region and the PFET region. The photoresist is then patterned to expose the NFET region. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the NFET region, and the photoresist may act as a mask to substantially prevent p-type impurities from being implanted into the PFET region. After the implant, the photoresist may be removed, such as by an acceptable ashing process.

After one or more well implants of the NFET region and PFET region, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

As illustrated in FIG. 2, after the fin structures 206, the nanostructures 203 and the STI region 208 are formed, the substrate 100 may include nanostructure regions NS and an isolation region IR. The fin structures 206 and the nanostructures 203 are formed in the nanostructure regions NS. The STI region 208 is formed in the isolation region IR. In FIG. 2, the isolation region IR is between the two immediately-adjacent nanostructures NS.

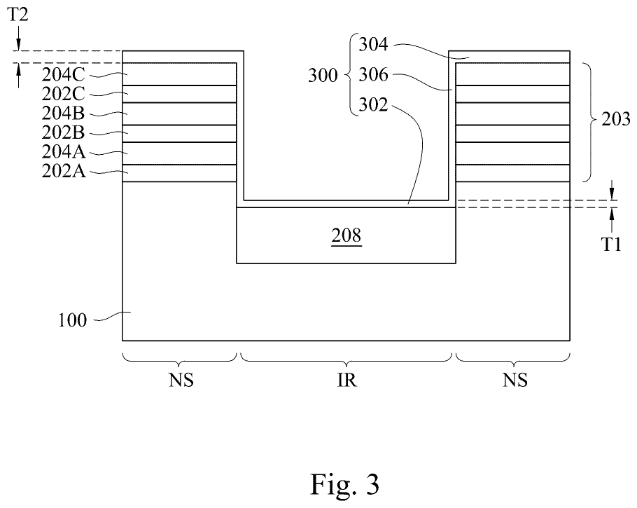

FIG. 3 illustrates forming a dielectric layer 300 over the structure as illustrated in FIG. 2, in accordance with some embodiments. FIG. 3 illustrates the cross-sectional view along a longitudinal axis of the nanostructures 203, in accordance with some embodiments.

As illustrated in FIG. 3, a dielectric layer 300 is deposited over the structure illustrated in FIG. 2. The dielectric layer 300 is formed across the nanostructure regions NS and the isolation region IR. The dielectric layer 300 may be formed of a dielectric material, and may be deposited by any suitable method, such as CVD, plasma-enhanced CVD (PECVD), FCVD, or the like. Dielectric materials may include silicon oxide (SiO₂), phosphosilicate glass (PSG), borosilicate glass (BSG), boron-doped phosphosilicate glass (BPSG), un-doped silicate glass (USG), or the like. Other insulation materials formed by any acceptable process may be used.

In some embodiments, the dielectric layer 300 may be formed by a plasma-enhanced atomic layer deposition (PEALD) process. Dielectric materials of the dielectric layer 300 formed by the PEALD process may include SiOₓ, AlOₓ, SiCₓ, SiOₓC_{y}N_{1-x-y}, SiNₓ or other low-k dielectric material. Other insulation materials formed by any acceptable process may be used. The dielectric layer 300 formed by the PEALD may have a horizontal portion 302 over the STI region 208, horizontal portions 304 over the topmost nanostructures 204C of the nanostructures 203 and vertical portions 306 over inner sidewalls of the nanostructures 203.

In some embodiments, material properties of the dielectric layer 300 formed by the PEALD process can be tuned by varying various deposition conditions such as power, pressure, and the mixing ratio of process gas to noble gas in the PEALD process. The horizontal portions 302 and 304 of the dielectric layer 300, formed by the PEALD process, may exhibit different material properties than the vertical portions 306 of the dielectric layer 300. Therefore, during a subsequent wet etching process, an etch rate of the horizontal portions 302 and 304 may be different from an etch rate of the vertical portions 306. For example, a density of the horizontal portions 302 and 304 of the dielectric layer 300 may be greater than a density of the vertical portions 306 of the dielectric layer 300. In this way, the vertical portions 306 can be removed in a subsequent wet etching process, while leaving the horizontal portions 302 and 304 remained on the STI region 208 and the topmost nanostructures 204C.

In FIG. 3, a thickness T1 of the horizontal portion 302 of the dielectric layer 300 over the STI region 208 is less than a thickness T2 of each of the horizontal portions 304 of the dielectric layer 300 over the nanostructures 204C, which is located at a higher elevation than the horizontal portion 302 over the STI region 208. This thickness difference may results from the PEALD process used in depositing the dielectric layer 300. During PEALD, the deposition rate can vary depending on the local surface topography and the aspect ratio of the features being coated. Specifically, the elevated nanostructures 204C present a more accessible surface for the reactive species in the plasma, leading to a higher deposition rate and consequently a greater thickness T2. In contrast, the recessed STI region 208, being less accessible, experiences a reduced deposition rate, resulting in a thinner dielectric thickness T1. In some other embodiments, the thickness T1 of the horizontal portion 302 may be greater than or substantially equal to the thickness T2 of the horizontal portions 304. Such thickness relationship between the thicknesses T1 and T2 can be adjusted by deposition conditions of the PEALD process.

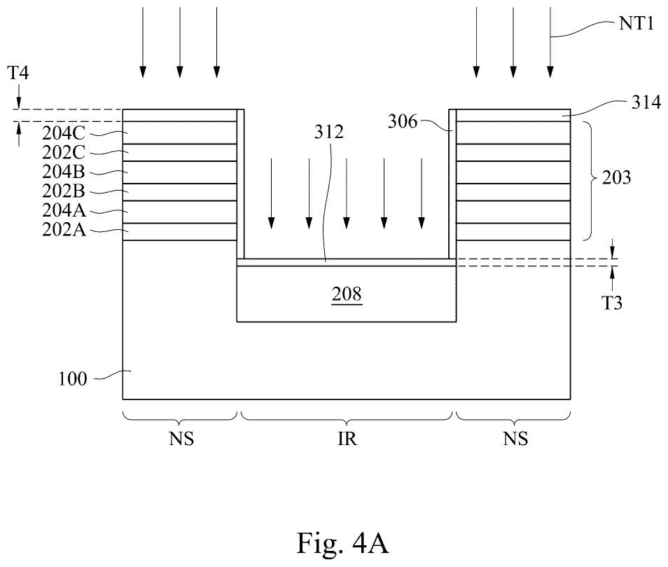

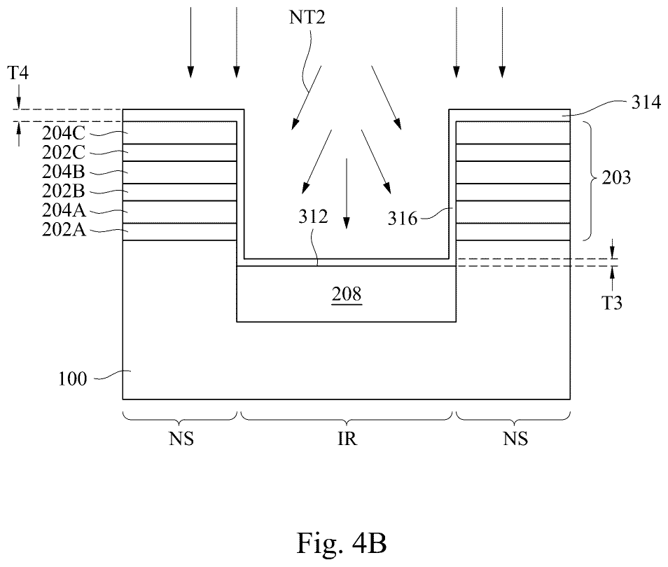

Reference is made to FIGS. 4A and 4B. FIG. 4A illustrates a cross-sectional views of performing a nitridation process NT1 to the structure as illustrated in FIG. 3, in accordance with some embodiments. FIG. 4B illustrates a cross-sectional views of performing another nitridation process NT2 to the structure as illustrated in FIG. 3, in accordance with some other embodiments. In one or more embodiments of the present disclosure, the nitridation process NT1 or NT2 may include exposing the dielectric layers 300 to a nitrogen-containing ambient, wherein precursors for the nitridation processes NT1 and NT2 may include nitrogen (N₂), ammonia (NH₃), combinations thereof, or the like.

Reference is made to FIG. 4A, which illustrates an example plasma nitridation process NT1 performed on the dielectric layer 300, in accordance to some embodiments. The nitridation process NT1 may be a direct plasma nitridation process with an applied bias, making it a directional plasma process. As illustrated by the arrows in FIG. 4A, plasmas in the plasma nitridation process NT1 are directed substantially perpendicularly to the top surface of the horizontal portions 302 and 304 of the dielectric layer 300 and parallel to sidewalls of the vertical portions 306 of the of the dielectric layer 300. Therefore, the direct plasma nitridation process NT1 ensures that the nitrogen atoms can be uniformly doped into the horizontal portions 302 and 304 of the dielectric layer 300 when performed in an N₂ and/or NH₃ ambient. Consequently, the nitridated horizontal portions 302 and 304 of the dielectric layer 300, referred as protection hard masks 312 and 314, exhibit a greater nitrogen concentration than the STI region 208. In some embodiments, t he nitridation process NT1 may result in a graded nitrogen concentration profile within the protection hard masks 312 and 314, where the nitrogen concentration is highest at the top surfaces of masks 312, 314 and gradually decreases as a function of depth. This nitrogen centration gradient may enhance the etch resistance and mechanical strength of the hard masks. Furthermore, in some embodiments where the dielectric layer 300 is an silicon-oxide-based material (e.g., SiOₓ), the incorporation of nitrogen may lead to the formation of silicon nitride (SiₓN_{y}) or oxynitride (SiON) phases within the protection hard masks 312 and 314, with a nitrogen concentration gradient.

As illustrated in FIG. 4A, the horizontal portion 302 of the dielectric layer 300 is nitridated as a protection hard mask 312 extending along the top surface of the STI region 208, and the horizontal portions 304 of the dielectric layer 300 are nitridated as protection hard masks 314 extending along the top surfaces of the topmost nanostructures 204C of the nanostructures 203. In some embodiments, the vertical portions 306 of the dielectric layer 300 remain un-nitridated after the nitridation process NT1 is performed, due to the vertical direction of the plasmas during the nitridation process NT1.

In some embodiments, the material of the protection hard masks 312 and 314 may include nitrdated SiOₓ, AlOₓ, SiCₓ, SiOₓC_{y}N_{1-x-y}, SiNₓ or other nitrdated low-k dielectric material. The protection hard masks 312 and 314 may have uniform nitrogen concentration at their top surfaces, and the concentration may decreases as a function of the depth measured from the top surfaces. In some embodiments, the plasma nitridation process NT1 may utilize N₂, NH₃, or N₂/NH₃ mixed gas with varied noble gas such as helium (He), neon (Ne), argon (Ar) and/or krypton (Kr). In some embodiments, operation pressure of the nitridation process NT1 is in a range from about 1 mTorr to about 100 mTorr. In some embodiments, nitrogen concentration of the protection hard masks 312 and 314 can be tuned by using gas species, gas ratio, source power, and bias power, and the operation pressure.

In a wet etching process, an etch rate of the nitridated horizontal portions 302 and 304, which serve as the protection hard masks 312 and 314, is slower than an etch rate of the un-nitridated vertical portions 306. Therefore, the vertical portions 306 of the dielectric layer 300 can be selectively removed by wet etching back. This selective removal occurs because the protection hard masks 312 and 314 have a significantly greater nitrogen concentration compared to the vertical portions 306, resulting in a reduced or retarded etch rate for these nitridated areas.

Reference is made to FIG. 4B, which illustrates a cross-section view of a thermal nitridation process NT2 performed on the dielectric layer 300, in accordance with some embodiments. The dielectric layer 300 formed by the PEALD process may have a material property difference such as a density difference between the horizontal portions 302, 304 and the vertical portions 306. For example, for the dielectric layer 300 formed by the PEALD process, the density of the horizontal portions 302, 304 may be greater than the density of the vertical portions 306. Therefore, after the thermal nitridation process NT2 is performed, material properties of the nitridated horizontal portions 302 and 304 may be different from that of the nitridated vertical portions 306.

As illustrated in FIG. 4B, the thermal nitridation process NT2 results in a uniform nitridation. Following the NT2 process, the horizontal portion 302 of the dielectric layer 300 becomes nitridated, forming a protective hard mask 312 over the STI region 208. Similarly, the horizontal portions 304 of the dielectric layer 300 are nitridated, creating protective hard masks 314 over the topmost nanostructures 204C of the nanostructures 203. Additionally, the vertical portions 306 of the dielectric layer 300 are nitridated, resulting in sacrificial hard masks 316 on the inner sidewalls of the nanostructures 203. In one or more embodiments, during a wet etching process, an etch rate of the sacrificial hard masks 316 is different from an etch rate of the protection hard masks 312 and 314, due to the material property difference (i.e., density difference) between the protection hard masks 312, 314 and the sacrificial hard masks 316.

In some embodiments, t he thermal nitridation process NT2 can utilize N₂, NH₃, or a mixture of N₂/NH₃ gases. In some embodiments, the thermal nitridation process NT2 is performed on the dielectric layer 300 in an N₂ or NH₃ ambient at a temperature in a range from about 600° C. to a peak of about 900° C. The pressure during this thermal nitridation process NT2 can be adjusted based on the desired film quality and the required nitrogen impurity concentration. The thermal nitridation NT2 effectively introduces a high and uniformly dispersed concentration of nitrogen impurities on the top surface of the horizontal portions 302 and 304 of the dielectric layer 300.

After the nitridation process NT1 or NT2 is performed, the protection hard mask 312 may have a thickness T3, and the protection hard masks 314 have a thickness T4. In FIGS. 4A and 4B, the thickness T3 is less than the thickness T4. In some embodiments, the thickness T3 of the protection hard mask 312 may be greater than or substantially equal to the thickness T4 of the protection hard masks 314.

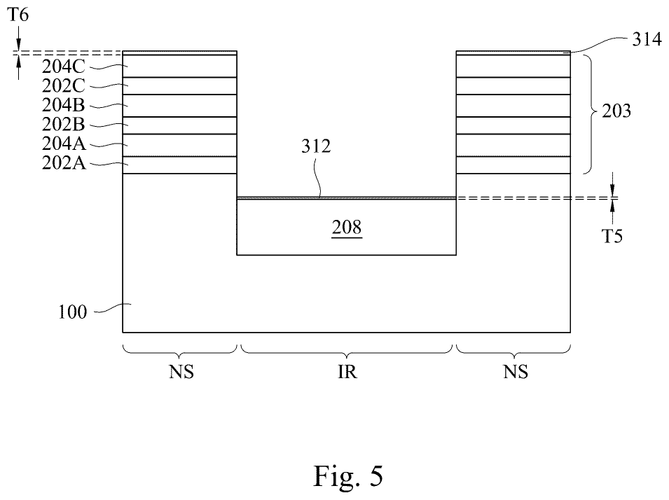

FIG. 5 illustrates performing a wet etching process to remove the vertical portions 306 as illustrated in FIG. 4A or remove the sacrificial hard masks 316 as illustrated in FIG. 4B. In some embodiments, wet chemicals of the wet etching process can include diluted hydrofluoric acid (HF), buffer oxide etch (BOE), H₃PO₄, standard clean-1 (SC1), or standard clean-2 (SC2). In some embodiments, the SC1 is a mixture of DI water, ammonium hydroxide (NH4OH), and hydrogen peroxide (H₂O₂). In some embodiments, the SC2 is a mixture of deionized (DI) water, hydrochloric (HCl) acid, and hydrogen peroxide (H₂O₂).

In FIG. 4A, the directional plasma nitridation process NT1 may cause material difference between the protection hard masks 312, 314 and the vertical portion 306 of the dielectric layer 300, so that for the wet etching process the etch rate of the protection hard masks 312 and 314 may be less the etch rate of the vertical portions 306 of the dielectric layer 300. Therefore, as illustrated in FIG. 5, the protection hard mask 312 over the STI region 208 and the protection hard masks 314 over the nanostructure 204C remains after the vertical portions 306 of the dielectric layer 300 or the sacrificial hard masks 316 are removed. In some embodiments that the dielectric layer 300 is formed by the PEALD process, the PEALD process may cause material differences such as a density difference between the horizontal portions 302, 304 and the vertical portions 306 of the dielectric layer 300. In FIG. 4B, due to the material difference between the horizontal portions 302, 304 and the vertical portions 306 of the dielectric layer 300, the etch rate of the protection hard masks 312 and 314 may be less than the etch rate of the sacrificial hard masks 316. Therefore, as illustrated in FIG. 5, the protection hard mask 312 over the STI region 208 and the protection hard masks 314 over the nanostructure 204C remains after the sacrificial hard masks 316 are removed. In FIG. 5, the inner sidewalls of the nanostructure 203 are exposed and the STI region 208 is protected by the protection hard mask 312.

As illustrated in FIG. 5, after the vertical portions 306 of the dielectric layer 300 or the sacrificial hard masks 316 are removed, the thickness T3 of the protection hard mask 312 is reduced to a thickness T5, and the thickness T4 of the protection hard mask 314 is reduced to a thickness T6. In FIG. 5, the thickness T5 is less than the thickness T6. In some embodiments, the thickness T5 may be greater than or substantially equal to the thickness T6. In some embodiments, each of the thickness T5 and the thickness T5 may be in a range from about 15 angstrom to about 30 angstrom. In some embodiments, a difference between the thickness T5 and the thickness T6 may be in a range from about 5 angstrom to about 10 angstrom. In some embodiments, a ratio of the thickness T5 to the thickness T6 may be in a range from about 1 to about 3. In some embodiments, a ratio of the thickness of T5 to a thickness of the STI region 208 may be in a range from about 0.01 to about 0.1.

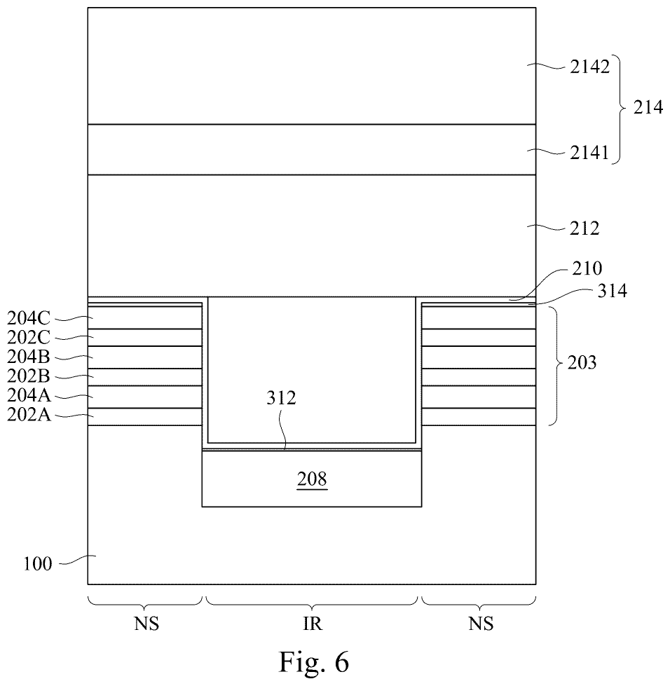

Reference is made to FIG. 6. FIG. 6 illustrates forming a dummy dielectric layer 210 over the protection hard masks 312, 314 and the exposed inner sidewall of the nanostructures 203 and forming a dummy gate layer 212 and mask layers 214 including mask layers 2141 and 2142 over the dummy dielectric layer 210.

As illustrated in FIG. 6, the dummy dielectric layer 210 is formed along the protection hard masks 312, 314 and the exposed inner sidewall of the nanostructures 203. The dummy dielectric layer 210 may be, for example, silicon oxide, silicon nitride, a combination thereof, or the like, and may be deposited or thermally grown according to acceptable techniques. A dummy gate layer 212 is formed over the dummy dielectric layer 210, and mask layer s 214 are formed over the dummy gate layer 212. The dummy gate layer 212 may be deposited over the dummy dielectric layer 210 and then planarized, such as by a CMP. The mask layers 2141 and 2142 of the mask layer s 214 may be deposited over the dummy gate layer 212. The dummy gate layer 212 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 212 may be deposited by physical vapor deposition (PVD), CVD, sputter deposition, or other techniques for depositing the selected material. The dummy gate layer 212 may be made of other materials that have a high etching selectivity from the etching of isolation regions. The mask layers 2141 and 2142 of the mask layers 214 may include, for example, silicon nitride, silicon oxynitride, or the like.

It is noted that the dummy dielectric layer 210 is shown covering the fin structures 206 and the nanostructures 203 for illustrative purposes only. In some embodiments, the dummy dielectric layer 210 may be deposited such that the dummy dielectric layer 210 covers the STI regions 208, such that the dummy dielectric layer 210 extends between the dummy gate layer 212 and the STI regions 208.

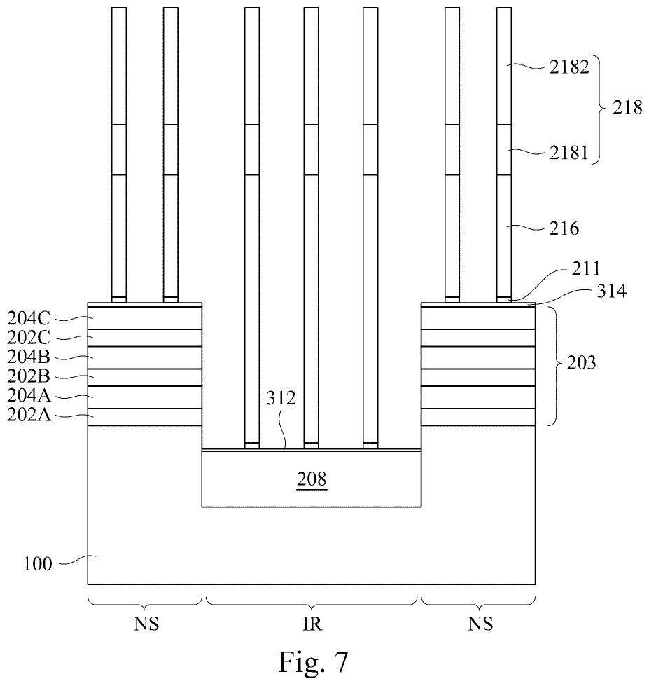

Reference is made to FIG. 7. FIG. 7 illustrates forming dummy gate s 216 and masks 218 including mask layers 2181 and 2182 by patterning the dummy gate layer 212 and the mask layers 2141 and 2142 of the mask layer 214, in accordance with some embodiments.

As illustrated in FIG. 7, the mask layers 2141 and 2142 of the mask layer s 214 may be patterned using acceptable photolithography and etching techniques to form masks 218 including masks 2181 and 2182. The pattern of the masks 218 then may be transferred to the dummy gate layer 212 and to the dummy dielectric layer 210 to form dummy gates 216 and dummy gate dielectrics 211, respectively. The dummy gates 216 cover respective channel regions of the fin structures 206. The pattern of the masks 218 may be used to physically separate each of the dummy gates 216 from adjacent dummy gates 216. The dummy gates 216 may also have a lengthwise direction substantially perpendicular to the lengthwise direction of respective fin structures 206. The dummy dielectrics 211 in the isolation region IR is lower than the dummy dielectrics 211 in the nanostructure regions NS. The dummy dielectrics 211 in the isolation region IR are formed between the STI region 208 and the protection hard mask 312.

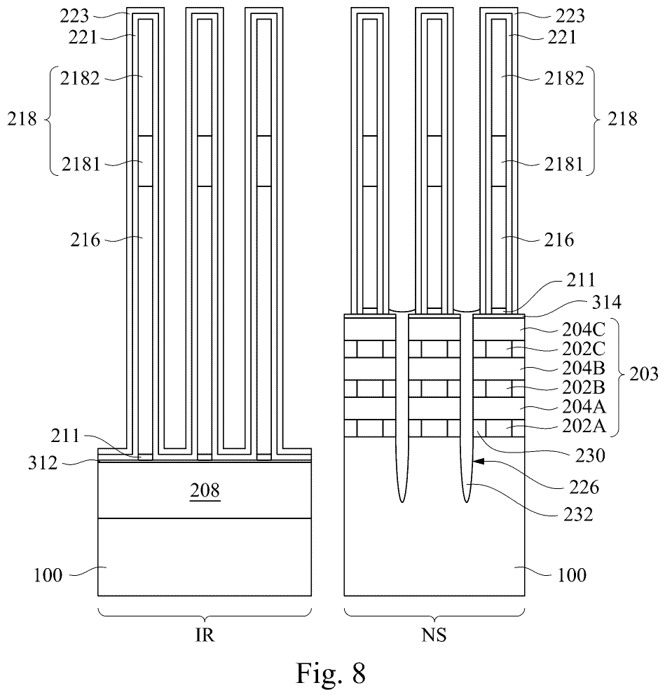

Reference is made to FIG. 8. FIG. 8 illustrates forming a first spacer layer 221 and a second spacer layer 223 over the dummy gate structure including the masks 218, the dummy gates 216 and the dummy dielectric s 211, in accordance with some embodiments. FIG. 8 illustrates cross-sectional views of the nanostructure region NS and the isolation region IR along a longitudinal axis of the nanostructures 203.

As illustrated in FIG. 8, a first spacer layer 221 and a second spacer layer 223 are formed over the structures illustrated in FIG. 7. The first spacer layer 221 and the second spacer layer 223 will be subsequently patterned to act as spacers for forming self-aligned source/drain regions.

In some embodiments, the first spacer layer 221 is formed on top surfaces of the protection hard mask 312 over t he STI regions 208, the inner sidewalls of the fin structures 206 and the nanostructures 203, top surfaces of the protection hard masks 314, sidewalls of the dummy gate dielectrics 211 and the dummy gates 216 and top surfaces and sidewalls of the masks 218 including the mask layers 2181 and 2182. The first spacer layer 221 may be formed of silicon oxide, silicon nitride, silicon oxynitride, or the like, using techniques such as thermal oxidation or deposited by CVD, ALD, or the like. The second spacer layer 223 may be formed of a material having a different etch rate than the material of the first spacer layer 223, such as silicon oxide, silicon nitride, silicon oxynitride, or the like, and may be deposited by CVD, ALD, or the like.

In FIG. 8, the first spacer layer 221 and the second spacer layer 223 are etched to form first spacers 221 and second spacers 223. As will be discussed in greater detail below, the first spacers 221 and the second spacers 223 act to self-align subsequently formed source and drain regions (collectively referred to as source/drain regions), as well as to protect sidewalls of the fin structures 206 and/or nanostructure 203 during subsequent processing. The first spacer layer 221 and the second spacer layer 223 may be etched using a suitable etching process, such as an isotropic etching process (e.g., a wet etching process), an anisotropic etching process (e.g., a dry etching process), or the like. In some embodiments, the material of the second spacer layer 223 has a different etch rate than the material of the first spacer layer 221, such that the first spacer layer 221 may act as an etch stop layer when patterning the second spacer layer 223 and such that the second spacer layer 223 may act as a mask when patterning the first spacer layer 221. For example, the second spacer layer 223 may be etched using an anisotropic etch process wherein the first spacer layer 221 acts as an etch stop layer, wherein remaining portions of the second spacer layer 223 form second spacers 223 as illustrated in FIG. 8. Thereafter, the second spacers 223 acts as a mask while etching exposed portions of the first spacer layer 221, thereby forming first spacers 221 as illustrated in the nanostructure region NS of FIG. 8.

As illustrated in FIG. 8, the first spacers 221 and the second spacers 223 are disposed on sidewalls of the fin structures 206 and/or nanostructures 203. In some embodiments, the spacers 221 and 223 only partially remain on sidewalls of the fin structures 206. In some embodiments, no spacer remains on sidewalls of the fin structures 206. In some embodiments, the second spacer layer 223 may be removed from over the first spacer layer 221 adjacent the masks 218, the dummy gates 216, and the dummy gate dielectrics 211, and the first spacers 221 are disposed on sidewalls of the masks 218, the dummy gates 216, and the dummy dielectrics 211. In some embodiments, a portion of the second spacer layer 223 may remain over the first spacer layer 221 adjacent the masks 218, the dummy gates 216, and the dummy gate dielectrics 211.

In some embodiments, the first spacers 221 on gate sidewalls (also called gate spacers) have a small thickness (e.g., in a range from about 1 nm to about 10 nm) so as to reduce gate-to-gate pitch without significant reduction in source/drain region size. In some embodiments, the first spacers 221 on gate sidewalls is formed of as low-dielectric constant (low-k) materials (e.g., porous silicon oxide) having a k-value, for example, less than about 3.5. The low-k material can aid in reducing parasitic capacitance between, for example, the subsequently formed metal gates and source/drain contacts.

The above disclosure generally describes a process of forming spacers. Other processes and sequences may be used. For example, fewer or additional spacers may be utilized, different sequence of steps may be utilized (e.g., the first spacers 221 may be patterned prior to depositing the second spacer layer 223), additional spacers may be formed and removed, and/or the like.

In FIG. 8, source/drain recesses 226 are formed in the fin structures 206, the nanostructures 203, and the substrate 100, in accordance with some embodiments. The source/drain recess 226 is formed in the nanostructure region NS.

Epitaxial source/drain regions will be subsequently formed in the source/drain recesses 226. The source/drain recesses 226 may extend through the protection hard mask 314, the first nanostructures 202 and the second nanostructures 204, and into the substrate 100. In some other embodiments, the fin structures 206 may be etched such that bottom surfaces of the source/drain recesses 226 are disposed below the top surfaces of the STI regions 208, or above the top surfaces of the STI regions 208. The source/drain recesses 226 may be formed by etching the fin structures 206, the nanostructures 203, and the substrate 100 using anisotropic etching processes, such as RIE, NBE, or the like. The first spacers 221, the second spacers 223, and the masks 218 mask portions of the fin structures 206, the nanostructures 203, and the substrate 100 during the etching processes used to form the source/drain recesses 226. A single etch process or multiple etch processes may be used to etch each layer of the nanostructures 203 and/or the fin structures 206. Timed etch processes may be used to stop the etching of the source/drain recesses 226 after the source/drain recesses 226 reach a target depth.

After the source/drain recess 226 are formed, portions of sidewalls of the layers of the nanostructures 203 formed of the first semiconductor materials (e.g., the first nanostructures 202) exposed by the source/drain recesses 226 are etched to form sidewall recesses between corresponding second nanostructures 204. Sidewalls of the first nanostructures 202 in recesses can be straight, concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202.

In FIG. 8, inner spacers 230 are formed in the sidewall recesses of the nanostructures 202. The inner spacers 230 may be formed by depositing an inner spacer layer (not separately illustrated) in the sidewall recesses of the nanostructures 202 and over the sidewall of the nanostructures 204. The inner spacers 230 act as isolation features between subsequently formed source/drain regions and gate structure. As will be discussed in greater detail below, source/drain regions will be formed in the source/drain recesses 226, and the first nanostructures 202 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 230. Although outer sidewalls of the inner spacers 230 are illustrated as being flush with sidewalls of the second nanostructures 204, the outer sidewalls of the inner spacers 230 may extend beyond or be recessed from sidewalls of the second nanostructures 204.

In FIG. 8, epitaxial source/drain regions 232 are formed in the source/drain recesses 226. In some embodiments, the source/drain regions 232 may exert stress on the second nanostructures 204, thereby improving device performance. As illustrated in FIG. 8, the epitaxial source/drain regions 232 are formed in the source/drain recesses 226 such that each dummy gate 216 and each protection hard mask 314 remaining in the nanostructure region NS are disposed between respective neighboring pairs of the epitaxial source/drain regions 232. In some embodiments, the first spacers 221 are used to separate the epitaxial source/drain regions 232 from the dummy gates 216, and the inner spacers 230 are used to separate the epitaxial source/drain regions 232 from the first nanostructures 202 by an appropriate lateral distance so that the epitaxial source/drain regions 232 do not short out with subsequently formed gates of the resulting GAA-FETs.

In some embodiments, the epitaxial source/drain regions 232 may include any acceptable material appropriate for n-type GAA-FETs. For example, if the second nanostructures 204 are silicon, the epitaxial source/drain regions 232 may include materials exerting a tensile strain on the second nanostructures 204, such as silicon carbide, phosphorous doped silicon carbide, silicon phosphide, or the like. In some embodiments, the epitaxial source/drain regions 232 may include any acceptable material appropriate for p-type GAA-FETs. For example, if the second nanostructures 204 are silicon, the epitaxial source/drain regions 232 may comprise materials exerting a compressive strain on the second nanostructures 204, such as silicon germanium, boron doped silicon germanium, germanium, germanium tin, or the like. The epitaxial source/drain regions 232 may have surfaces raised from respective upper surfaces of the nanostructures 203 and may have facets.

The epitaxial source/drain regions 232 may be implanted with dopants to form source/drain regions, followed by an anneal. The source/drain regions may have an impurity concentration of between about 1×10¹⁷ atoms/cm³ and about 1×10²² atoms/cm³. The n-type and/or p-type impurities for source/drain regions may be any of the impurities previously discussed. In some embodiments, the epitaxial source/drain regions 232 may be in situ doped during growth.

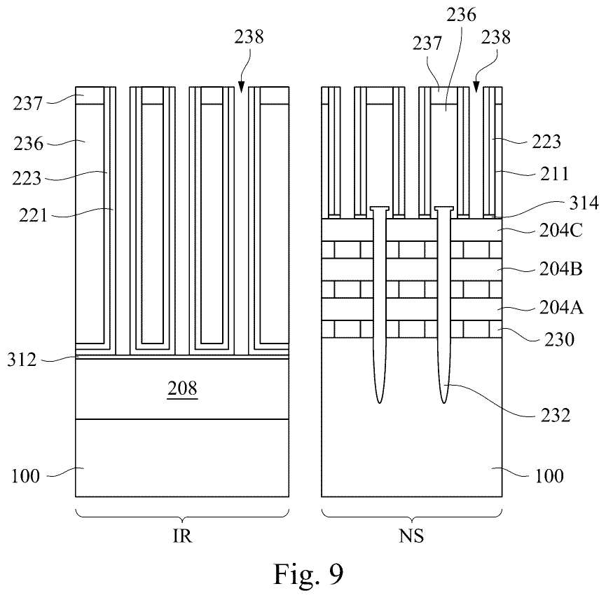

Reference is made to FIG. 9. FIG. 9 illustrates forming an interlayer dielectric layer 236 over the source/drain regions 232 and between the first spacer layers 221 and the second spacer layers 223. FIG. 9 illustrates cross-sectional views of the nanostructure region NS and the isolation region IR along a longitudinal axis of the nanostructures 203.

As illustrated in FIG. 9, an ILD layer 236 is deposited over the structure illustrated in FIG. 8. The ILD layer 236 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) is disposed between the ILD layer 236 and the epitaxial source/drain regions 232, the masks 21 8, and the first spacers 221. The CESL may include a dielectric material, such as, SiN, SiOₓ, SiCN, SiON, SiOCN, Al₂O₃, HfO₂, ZrO₂, HfAlOₓ, and HfSiOₓ, or the like, having a different etch rate than the material of the overlying ILD layer 236.

After the ILD layer 236 is formed, a planarization process, such as a CMP, may be performed to level the top surface of the ILD layer 236 with the top surfaces of the dummy gates 216 or the masks 218. The planarization process may also remove the masks 218 on the dummy gates 216, and portions of the first spacers 221 along sidewalls of the masks 218. After the planarization process, top surfaces of the dummy gates 216, the first spacers 221, and the ILD layer 236 are level within process variations. Accordingly, the top surfaces of the dummy gates 216 may be exposed through the ILD layer 236. In some embodiments, the masks 218 may remain, in which case the planarization process levels the top surface of the ILD layer 236 with top surface of the masks 218 and the first spacers 221.

As illustrated in FIG. 9, the ILD layer 236 is etched back to fall below the dummy gates 216, and then a protective layer 237 is formed over the ILD layer 236. The protective layer 237 has a higher etch resistance to a following metal gate etch back (MGEB) process than that of the ILD layer 236, and thus the protective layer 237 can serve to protect the underlying ILD layer 236 from potential loss or damage caused by the following MGEB process. The protective layer 237 can be formed by, for example, depositing a layer of dielectric material globally over the substrate 100, followed by performing a planarization process, such as CMP, on the deposited layer of dielectric material until the dummy gates 216 get exposed. In some embodiments, the ILD layer 236 is an oxide-based dielectric material (e.g., silicon oxide), and the protective layer 237 is a nitride-based dielectric material (e.g., silicon nitride).

In FIG. 9, the dummy gates 216, and the masks 218 if present, are removed in one or more etching steps, so that gate trenches 238 are formed between corresponding gate spacers 221. In some embodiments, portions of the dummy gate dielectrics 211 in the gate trenches 238 are also be removed. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than the protective layer 237 or the first spacers 221. In some embodiments, the removal process to the dummy gate dielectrics 211 of oxide may include, f or example, an oxide removal wet etching process using dilute hydrofluoric (dHF) acid. Each gate trench 238 exposes and/or overlies portions of nanostructures 204, which will serve as channel regions in subsequently completed GAA-FETs. The nanostructures 204 serving as the channel regions are disposed between neighboring pairs of the epitaxial source/drain regions 232. During the removal, the dummy dielectrics 211 may be used as etch stop layers when the dummy gates 216 are etched. The dummy dielectrics 211 may then be removed after the removal of the dummy gates 216.

In some embodiments, the dummy dielectrics 211 may be oxide material such as silicon oxide and the STI region 208 may also include oxide material. In one or more embodiments of the present disclosure, the protection hard masks 312 are formed between the dummy dielectrics 211 and the STI region 208 before removing the dummy dielectrics 211, so that the protection hard masks 312 may be a nitride protection layer protecting the STI region 208 when removing the dummy dielectrics 211. Therefore, selectively forming the protection hard masks 312 on the top surface of STI region 208 can reduce the risk of device degradation and metal gate line-to-line leakage, and it effective to prevent damage to the STI region 208 after oxide removal process for removing the dummy dielectrics 211 in replacement gate (RPG) loop and the risk of device degradation and the metal gate line-to-line leakage can be reduced.

The first nanostructures 202 in the gate trenches are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-to-sheet spaces if the nanostructures 204 are nanosheets). This step can be referred to as a channel release process. At this interim processing step, the spaces between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments the second nanostructures 204 may be trimmed to have a substantial rounded shape (i.e., cylindrical) due to the selective etching process for completely removing the first nanostructures 202. In that case, the resultant second nanostructures 204 can be called nanowires.

In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202. In some embodiments, both the channel release step and the previous step of laterally recessing first nanostructures 202 use a selective etching process that etches first nanostructures 202 (e.g., SiGe) at a faster etch rate than etching second nanostructures 204 (e.g., Si), and therefore these two steps may use the same etchant chemistry in some embodiments. In this case, the etching time/duration of channel release step is longer than the etching time/duration of the previous step of laterally recessing first nanostructures 202, so as to completely remove the sacrificial nanostructures 202.

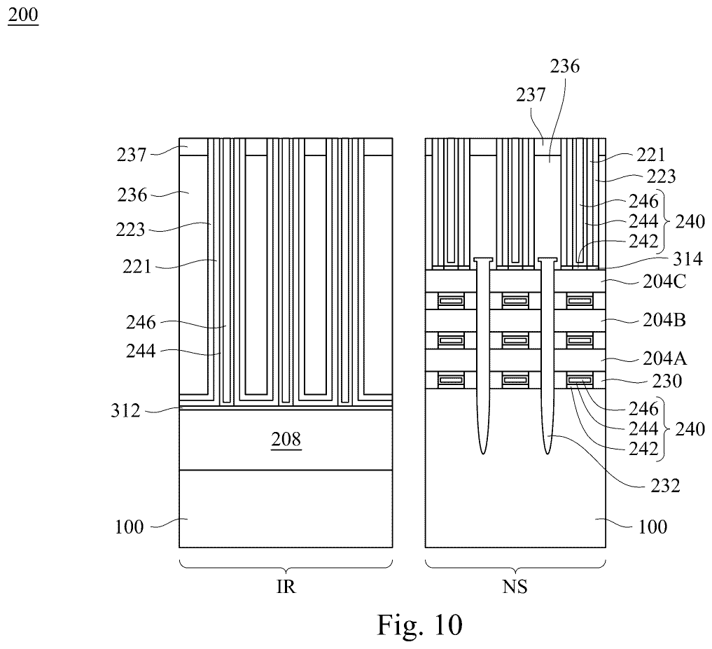

Continuing to FIG. 9, FIG. 10 illustrates forming replacement gate structures 240 in the gate trenches 238. FIG. 10 illustrates cross-sectional views of the nanostructure region NS and the isolation region IR along a longitudinal axis of the nanostructures 203.

In FIG. 10, replacement gate structures 240 are respectively formed in the gate trenches 238 to surround each of the nanosheets 204 suspended in the gate trenches 238. The gate structures 240 may be final gates of GAA FETs. The final gate structure may be a high-k/metal gate stack, however other compositions are possible. In some embodiments, each of the gate structures 240 forms the gate associated with the multi-channels provided by the plurality of nanosheets 204. For example, high-k/metal gate structures 240 are formed within the sheet-to-sheet spaces provided by the release of nanosheets 204. In various embodiments, the high-k/metal gate structure 240 includes an interfacial layer 242 formed around the nanosheets 204, a high-k gate dielectric layer 244 formed around the interfacial layer 242, and a gate metal layer 246 formed around the high-k gate dielectric layer 244 and filling a remainder of gate trenches 238. Formation of the high-k/metal gate structures 240 may include one or more deposition processes to form various gate materials, followed by a CMP process to remove excessive gate materials, resulting in the high-k/metal gate structures 240 having top surfaces level with a top surface of the protective layer 237. As illustrated in the cross-sectional view of FIG. 10, the high-k/metal gate structure 240 surrounds each of the nanosheets 204, and thus is referred to as a gate of a GAA FET.

In some embodiments, the interfacial layer 242 is silicon oxide formed on exposed surfaces of semiconductor materials in the gate trenches 238 by using, for example, thermal oxidation, chemical oxidation, wet oxidation or the like. As a result, surface portions of the nanosheets 204 exposed in the gate trenches 238 are oxidized into silicon oxide to form the interfacial layer 242. In some embodiments, the interfacial layer 242 is silicon oxide formed on exposed surfaces of semiconductor materials in the gate trenches 238 by using, for example, suitable deposition process such as plasma-enhanced CVD (PECVD), atomic layer deposition (ALD) or the like. In some embodiments, the interfacial layer 242 formed by suitable deposition process may be deposited over sidewalls of the first spacers 221, the protection hard mask 312 and exposed surfaces in the gate trenches 238.

In some embodiments, the high-k gate dielectric layer 244 includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 246 includes one or more metal layers. For example, the gate metal layer 246 may include one or more work function metal layers stacked one over another and a fill metal filling up a remainder of gate trenches 238. The one or more work function metal layers in the gate metal layer 246 provide a suitable work function for the high-k/metal gate structures 240. For an n-type GAA FET, the gate metal layer 246 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the gate metal layer 246 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 246 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

As illustrated in FIG. 10, a semiconductor device 200 is provided. In one or more embodiments of the present disclosure, the semiconductor device 200 may include the nanostructures 204A-C as channel regions, the gate structures 240 wrapping around the nanostructures 204A-C and the source/drain regions 232 on opposite sides of the nanostructures 204A-C. In the isolation region IR, the gate structures 240 extend over the protection hard masks 312. In the nanostructure region NS, the gate structures 240 are in contact with sidewall of the protection hard masks 314. The semiconductor device 200 may include the protection hard masks 312 and 314. The protection hard mask 312 may protect the STI region 208 during RPG loop. The protection hard masks 314 may remain between the first spacers 221 and the topmost nanostructures 204C. In some embodiments, the source/drain regions 232 are between two immediately-adjacent protection hard masks 314. The ILD layers 236 are formed over the source/drain regions 232 and extend between the protection hard masks 314 and the source/drain regions 232. In the nanostructure region NS, the nanostructures 204A-C, the gate structure 240 and the source/drain regions 232 may form transistors over the substrate 100.

It is noted that the gate structure 240 over the protection hard mask 312 on the STI region 208 may be a gate structure wrapping around the channel regions in a nanostructure region NS. On the other hands, in some embodiments, each gate structure 240 may have a first portion directly over the protection hard mask 312 in one of the isolation regions IR and a second portion between the protection hard masks 314 between the spacer layers 221 and the nanostructures 204C in one of the nanostructure regions NS in a direction perpendicular to the longitudinal axis of the nanostructures 203.

According to one or more embodiments of the present disclosure, a method of forming a semiconductor device includes a number of operations. A dielectric layer is formed over a plurality of nanostructures arranged in a vertical manner and an isolation structure adjacent the nanostructures. The dielectric layer is nitridated. A vertical portion of the nitridated dielectric layer over a sidewall of the nanostructure is removed, wherein a first horizontal portion of the nitridated dielectric layer remains over the isolation structure, and a second horizontal portion of the nitridated dielectric layer remains over a topmost one of the nanostructures. A source/drain region is formed through the second horizontal portion of the nitridated dielectric layer and the nanostructures. A gate structure is formed and wraps around the nanostructures. In one or more embodiments of the present disclosure, the method further includes forming a dummy gate structure over the second horizontal portion of the nitridated dielectric layer, wherein the dummy gate structure is removed before forming the gate structure. In some embodiments, forming the dummy gate structure includes forming an oxide layer over the first horizontal portion of the nitridated dielectric layer. In one or more embodiments of the present disclosure, the method further includes forming a spacer layer over the first horizontal portion of the nitridated dielectric layer, wherein the gate structure is formed in a gate trench within the spacer layer. In one or more embodiments of the present disclosure, the dielectric layer is nitridated by a plasma-enhanced nitridation process. In one or more embodiments of the present disclosure, the dielectric layer is nitridated by a thermal nitridation process. In one or more embodiments of the present disclosure, the dielectric layer is formed by a plasma-enhanced atomic layer deposition process. In one or more embodiments of the present disclosure, the gate structure is formed over the first horizontal portion of the nitridated dielectric layer. In one or more embodiments of the present disclosure, the gate structure is in contact with a sidewall of the second horizontal portion of the nitridated dielectric layer.

According to one or more embodiments of the present disclosure, a method of forming a semiconductor device includes a number of operations. A semiconductor fin is formed and includes first nanostructures and second nanostructures alternating with the first nanostructures. A shallow trench isolation (STI) region is formed and abuts a lower portion of the semiconductor fin. A dielectric layer is formed and has a first portion over the STI region and a second portion over a sidewall of the semiconductor fin. The first portion of the dielectric layer is converted into a first nitridated mask. The second portion of the dielectric layer is removed to expose the sidewall of the semiconductor fin. The first nanostructures is replaced with a gate structure wrapping around the second nanostructures, while the first nitridated mask remains over the STI region. In one or more embodiments of the present disclosure, the method further includes converting a third portion of the dielectric layer into a second nitridated mask positioned over the top surface of the semiconductor fin. In some embodiments, the second nitridated mask has a different thickness than the first nitridated mask. In one or more embodiments of the present disclosure, the second portion of the dielectric layer remains un-nitridated during converting the first portion of the dielectric layer into the first nitridated mask. In one or more embodiments of the present disclosure, the second portion of the dielectric layer is nitridated during converting the first portion of the dielectric layer into the first nitridated mask. In one or more embodiments of the present disclosure, the first portion of the dielectric layer has a density greater than a density of the second portion of the dielectric layer. In one or more embodiments of the present disclosure, removing the second portion of the dielectric layer is performed such that the first portion is trimmed from a first thickness to a second thickness. In one or more embodiments of the present disclosure, converting the first portion of the dielectric layer into the first nitridated mask comprises nitridating the first portion of the dielectric layer in an N₂ or NH₃ ambient.

According to one or more embodiments of the present disclosure, a semiconductor device includes a shallow trench isolation (STI) region, a first nitrogen-containing mask, a first gate structure, a transistor, a gate spacer and a second nitrogen-containing mask. The STI region is in a substrate. The first nitrogen-containing mask is over the STI region. The first gate structure is over the STI region and spaced apart from the STI region by the first nitrogen-containing mask. The transistor is over the substrate. The transistor includes a second gate structure and source/drain regions on opposite sides of the gate structure. The gate spacer is on a sidewall of the second gate structure. The second nitrogen-containing mask is under a bottom surface of the gate spacer. The second nitrogen-containing mask is formed of a same material composition as the first nitrogen-containing mask. In one or more embodiments of the present disclosure, the first nitrogen-containing mask comprises SiOₓ, AlOₓ, SiCₓ, SiOₓC_{y}N_{1-x-y}, or SiNₓ. In one or more embodiments of the present disclosure, the first nitrogen-containing mask has a thickness different from a thickness of the second nitrogen-containing mask.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first semiconductor fin and a second semiconductor fin over a substrate;
forming an isolation region between the first semiconductor fin and the second semiconductor fin;
forming a dielectric layer over the isolation region;
nitridating the dielectric layer; and
forming a gate structure over the nitridated dielectric layer.

2. The method of claim 1, wherein the dielectric layer is nitridated by a plasma process.

3. The method of claim 1, wherein the dielectric layer is nitridated by a thermal nitridation process.

4. The method of claim 1, wherein the dielectric layer is nitridated in an N₂ or NH₃ ambient.

5. The method of claim 1, wherein the dielectric layer is formed by a plasma-enhanced atomic layer deposition process.

6. The method of claim 1, wherein forming the dielectric layer comprises forming a first portion of the dielectric layer over the isolation region and second portions over sidewalls of the first and second semiconductor fins, and the method further comprises:
removing the second portions from the sidewalls of the first and second semiconductor fins.

7. The method of claim 6, wherein nitridating the dielectric layer is performed such that the first portion of the dielectric layer is nitridated, and the second portions of the dielectric layer are un-nitridated.

8. The method of claim 6, wherein nitridating the dielectric layer is performed such that the first portion and the second portions of the dielectric layer are nitridated.

9. The method of claim 6, wherein a density of the first portion of the dielectric layer is different from a density of the second portions of the dielectric layer.

10. A method comprising:
forming a semiconductor fin comprising first nanostructures and second nanostructures alternating with the first nanostructures;
forming a shallow trench isolation (STI) region abutting a lower portion of the semiconductor fin;
forming a dielectric layer having a first portion over the STI region and a second portion over a sidewall of the semiconductor fin;
converting the first portion of the dielectric layer into a first nitridated mask;
removing the second portion of the dielectric layer to expose the sidewall of the semiconductor fin; and
replacing the first nanostructures with a gate structure wrapping around the second nanostructures, while the first nitridated mask remains over the STI region.

11. The method of claim 10, further comprising:
converting a third portion of the dielectric layer into a second nitridated mask positioned over a top surface of the semiconductor fin.

12. The method of claim 11, wherein the second nitridated mask has a different thickness than the first nitridated mask.

13. The method of claim 10, wherein the second portion of the dielectric layer remains un-nitridated during converting the first portion of the dielectric layer into the first nitridated mask.

14. The method of claim 10, wherein the second portion of the dielectric layer is nitridated during converting the first portion of the dielectric layer into the first nitridated mask.

15. The method of claim 10, wherein the first portion of the dielectric layer has a density greater than a density of the second portion of the dielectric layer.

16. The method of claim 10, wherein removing the second portion of the dielectric layer is performed such that the first portion is trimmed from a first thickness to a second thickness.

17. The method of claim 10, wherein converting the first portion of the dielectric layer into the first nitridated mask comprises nitridating the first portion of the dielectric layer in an N₂ or NH₃ ambient.

18. A semiconductor device comprising:
a shallow trench isolation (STI) region in a substrate;
a first nitrogen-containing mask over the STI region;
a first gate structure over the STI region and spaced apart from the STI region by the first nitrogen-containing mask;
a transistor over the substrate, the transistor comprising a second gate structure and source/drain regions on opposite sides of the gate structure;
a gate spacer on a sidewall of the second gate structure; and
a second nitrogen-containing mask under a bottom surface of the gate spacer, wherein the second nitrogen-containing mask is formed of a same material composition as the first nitrogen-containing mask.

19. The semiconductor device of claim 18, wherein the first nitrogen-containing mask comprises SiOₓ, AlOₓ, SiCₓ, SiOₓC_{y}N_{1-x-y}, or SiNₓ.

20. The semiconductor device of claim 18, wherein the first nitrogen-containing mask has a thickness different from a thickness of the second nitrogen-containing mask.
